(19) United States
(12) Patent Application Publication
(10) Pub. No.: US 2026/0026018 A1
(43) Pub. Date: Jan. 22, 2026

(54) SEMICONDUCTOR STRUCTURE AND METHOD FOR FABRICATING THE SAME

(71) Applicant: Taiwan Semiconductor Manufacturing Company, Ltd., Hsinchu (TW)

(72) Inventors: Hsu Tung Yen, Hsinchu (TW); Ling-Sung Wang, Hsinchu (TW)

(73) Assignee: Taiwan Semiconductor Manufacturing Company, Ltd., Hsinchu (TW)

(21) Appl. No.: 18/780,450

(22) Filed: Jul. 22, 2024

(51) Int. Cl. H10D 1/47

(52) U.S. Cl. CPC H10D 1/47

(57) ABSTRACT

A resistor including a first resistor wiring, a second resistor wiring, a first spare resistor wiring, a first node, a second spare resistor wiring and a second node is provided. The first resistor wiring is electrically connected to the second resistor wiring through a first switch of the first node, and the first resistor wiring is electrically connected to the first spare resistor wiring through a second switch of the first node. The first spare resistor wiring is electrically connected to the second spare resistor wiring through the second node, and the second spare resistor wiring is electrically connected to the second resistor wiring through a third switch of the first node.

### BACKGROUND

Integrated chips are formed on semiconductor die including millions or billions of transistor devices. The transistor devices are configured to act as switches and/or to produce power gains so as to enable logical functionality for an integrated chip (e.g., form a processor configured to perform logic functions). Integrated chips also include passive devices, such as capacitors, resistors, inductors, varactors, etc. Therefore, the improved the resistors, such as variable resistors as well as the improved process of fabricating the resistors are desired as a development of a semiconductor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a top view of a variable resistor in accordance with some embodiments of the disclosure.

FIG. 2A schematically illustrates a circuit diagram of the first node or the first switch circuit in accordance with some embodiments of the disclosure.

FIG. 2B schematically illustrates a circuit diagram of the second node or the second switch circuit in accordance with some embodiments of the disclosure.

FIG. 2C schematically illustrates a circuit diagram of the third node or the third switch circuit in accordance with some embodiments of the disclosure.

FIG. 2D schematically illustrates a circuit diagram of the fourth node or the fourth switch circuit in accordance with some embodiments of the disclosure.

FIG. 3 schematically illustrate a top view of the variable resistor operated in an operation mode in accordance with the first embodiment of the disclosure.

FIG. 4 schematically illustrate a top view of the variable resistor operated in an operation mode in accordance with the second embodiment of the disclosure.

FIG. 5 schematically illustrate a top view of the variable resistor operated in an operation mode in accordance with the third embodiment of the disclosure.

FIG. 6 schematically illustrate a top view of the variable resistor operated in an operation mode in accordance with the fourth embodiment of the disclosure.

FIG. 7 schematically illustrate a top view of the variable resistor operated in an operation mode in accordance with the fifth embodiment of the disclosure.

FIG. 8A schematically illustrates a perspective view of a metal-oxide-semiconductor field effect transistor (MOSFET) fabricated by Front-End-of Line (FEOL) processes.

FIG. 8B schematically illustrates a perspective view of a thin film transistor (TFT) fabricated by Back-End-of Line (BEOL) processes.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

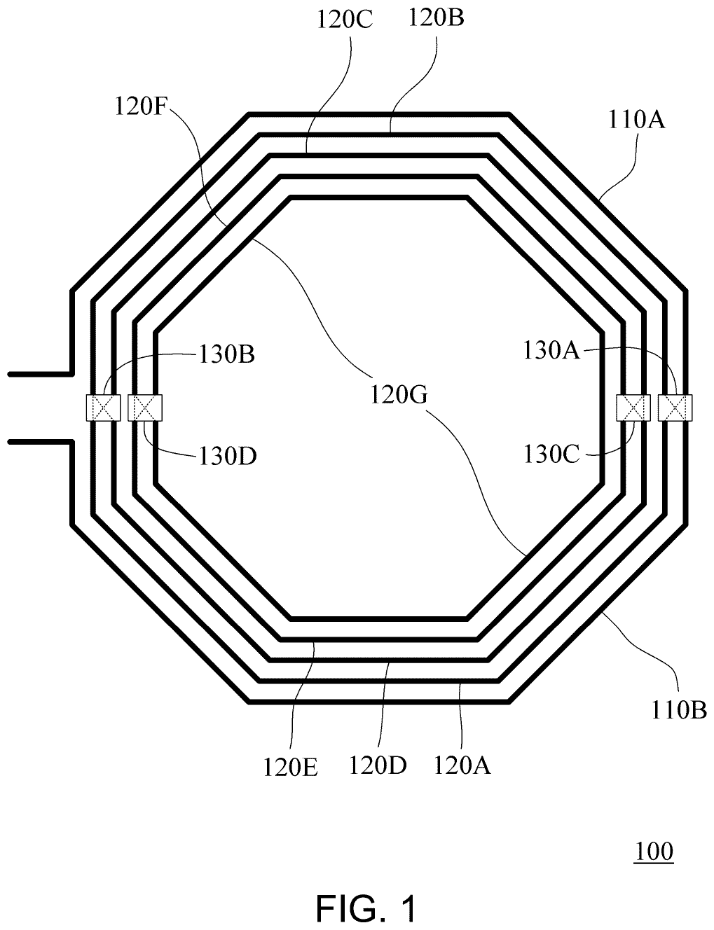

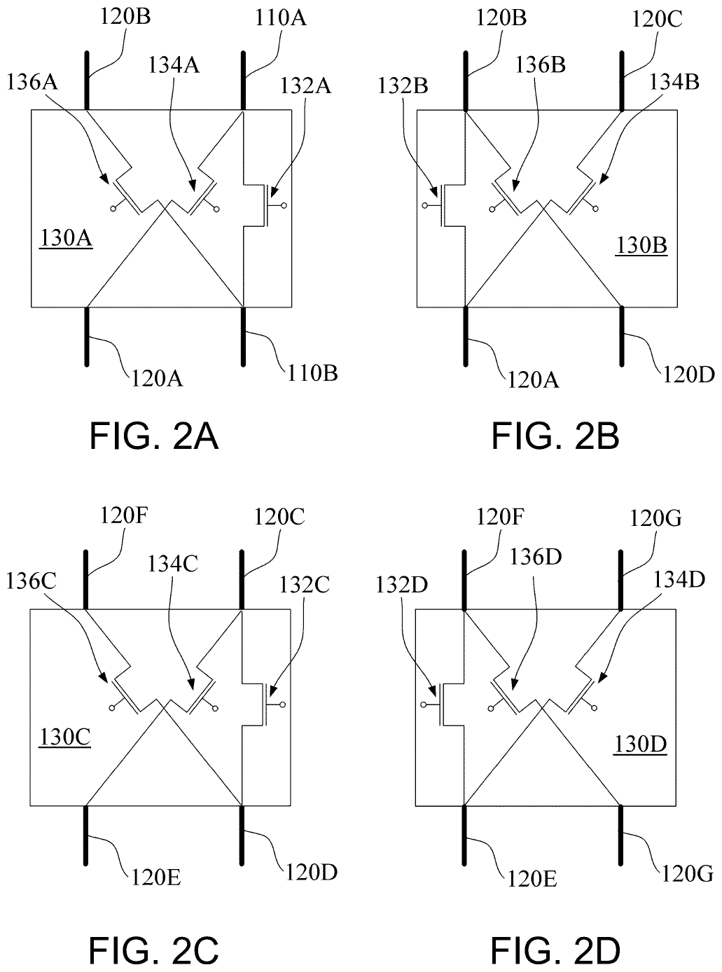

FIG. 1 schematically illustrates a top view of a variable resistor 100 in accordance with some embodiments of the disclosure. FIG. 2A schematically illustrates a circuit diagram of the first node or the first switch circuit 130A in accordance with some embodiments of the disclosure. FIG. 2B schematically illustrates a circuit diagram of the second node or the second switch circuit 130B in accordance with some embodiments of the disclosure. FIG. 2C schematically illustrates a circuit diagram of the third node or the third switch circuit 130C in accordance with some embodiments of the disclosure. FIG. 2D schematically illustrates a circuit diagram of the fourth node or the fourth switch circuit 130D in accordance with some embodiments of the disclosure.

Referring to FIG. 1, the variable resistor 100 at least includes a first resistor wiring 110A, a second resistor wiring 110B, a first spare resistor wiring 120A and a first node or switch circuit 130A. The first resistor wiring 110A is electrically connected to the second resistor wiring 110B and the first spare resistor wiring 120A through different parts of the first node or switch circuit 130A. The first resistor wiring 110A includes a first end and a second end opposite to the first end, wherein the first end of the first resistor wiring 110A is referred as to a current input end, and the second end of the first resistor wiring 110A is electrically connected to the first node or switch circuit 130A. The second resistor wiring 110B includes a first end and a second end opposite to the first end, wherein the first end of the second resistor wiring 110B is electrically connected to the first node or switch circuit 130A, and the second end of the second resistor wiring 110B is referred as to a current output end. The first resistor wiring 110A and the second resistor wiring 110B may be arranged along a first ring-shaped layout path (e.g., an octagonal ring-shaped layout path or other suitable types of ring-shaped layout path), wherein the first resistor wiring 110A is distributed in an upper region of the first ring-shaped layout path, and the second resistor wiring 110B is distributed in a bottom region of the first ring-shaped layout path. The first resistor wiring 110A and the second resistor wiring 110B may be substantially identical or different in resistance. The first resistor wiring 110A and the second resistor wiring 110B may be made from same material or different materials. The first resistor wiring 110A and the second resistor wiring 110B are substantially identical or different in linewidth, the length and/or the thickness. Through properly control of the linewidth, the length and/or the thickness, desired resistance of the first resistor wiring 110A and the second resistor wiring 110B can be obtained. For example, as illustrated in FIG. 1, the first resistor wiring 110A and the second resistor wiring 110B are made from the same ultra-thin metallic material (e.g., copper or alloys thereof), and the first resistor wiring 110A and the second resistor wiring 110B are substantially identical in linewidth, the length and the thickness. The width of the first resistor wiring 110A may range from about 1.5 micrometers to about 2.5 micrometers, the thickness of the first resistor wiring 110A may range from about 2 micrometers to about 10 micrometers, and the ratio of the width of the first resistor wiring 110A to the thickness the first resistor wiring 110A may range from about 0.18 to about 1.25. The width of the second resistor wiring 110B may range from about 1.5 micrometers to about 2.5 micrometers, the thickness of the second resistor wiring 110B may range from about 2 micrometers to about 10 micrometers, the ratio of the width of the second resistor wiring 110B to the thickness the second resistor wiring 110B may range from about 0.18 to about 1.25. The width of the first spare resistor wiring 120A ranges from about 1.5 micrometers to about 2.5 micrometers, the thickness of the first spare resistor wiring 120A ranges from about 2 micrometers to about 10 micrometers, and the ratio of the width of the first spare resistor wiring 120A to the thickness the first spare resistor wiring 120A may range from about 0.18 to about 1.25. The spacing between the first spare resistor wiring 120A and the second resistor wiring 110B may range from about 0.5 micrometers to about 2 micrometers. Furthermore, the ratio of the width of the first resistor wiring 110A, the second resistor wiring 110B or the first spare resistor wiring 120A to the spacing between the first spare resistor wiring 120A and the second resistor wiring 110B may range from about 0.75 to about 5.

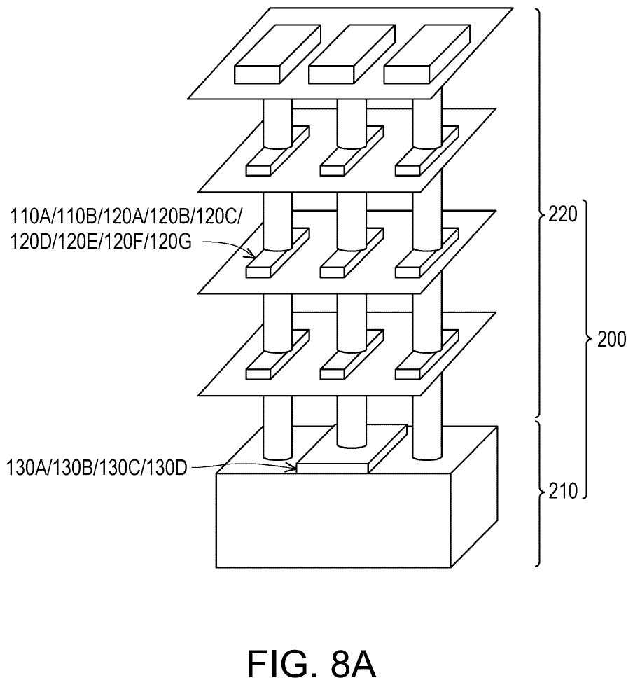

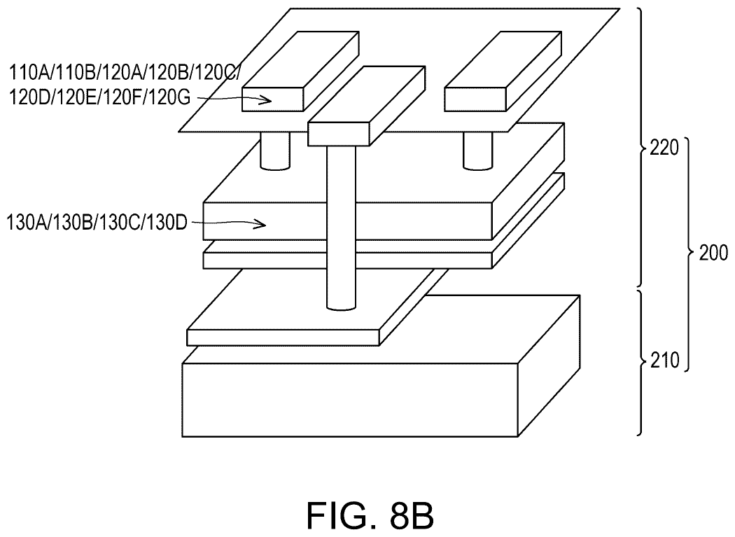

Referring to FIG. 2A, the first resistor wiring 110A is electrically connected to the second resistor wiring 110B through a first switch 132A (e.g., a first transistor) of the first node or switch circuit 130A. The first resistor wiring 110A and the second resistor wiring 110B are electrically connected to source/drain electrodes of the first switch 132A, respectively. The electrical connection between the first resistor wiring 110A and the second resistor wiring 110B is determined by the state of the first switch 132A of the first node or switch circuit 130A. In other words, the first resistor wiring 110A and the second resistor wiring 110B are electrically connected in series by the first switch 132A of the first node or switch circuit 130A when the first switch 132A is turned-on or enabled. In some embodiments, as illustrated in FIG. 8A, the first switch 132A of the first node or switch circuit 130A includes a metal-oxide-semiconductor field effect transistor (MOSFET) fabricated by Front-End-of Line (FEOL) processes. In some other embodiments, as illustrated in FIG. 8B, the first switch 132A of the first node or switch circuit 130A includes a thin film transistor (TFT) fabricated by Back-End-of Line (BEOL) processes. In some embodiments, the first switch 132A of the first node or switch circuit 130A is a n-type MOSFET. In some alternative embodiments, the first switch 132A of the first node or switch circuit 130A is a p-type MOSFET.

The first resistor wiring 110A is electrically connected to the first spare resistor wiring 120A through a second switch 134A (e.g., a second transistor) of the first node or switch circuit 130A. The first resistor wiring 110A and the first spare resistor wiring 120A are electrically connected to source/drain electrodes of the second switch 134A, respectively. The electrical connection between the first resistor wiring 110A and the first spare resistor wiring 120A is determined by the state of the second switch 134A of the first node or switch circuit 130A. In other words, the first resistor wiring 110A and the first spare resistor wiring 120A are electrically connected in series by the second switch 134A of the first node or switch circuit 130A when the second switch 134A is turned-on or enabled. In some embodiments, as illustrated in FIG. 8A, the second switch 134A of the first node or switch circuit 130A includes a metal-oxide-semiconductor field effect transistor (MOSFET) fabricated by Front-End-of Line (FEOL) processes. or a thin film transistor (TFT) fabricated by Back-End-of Line (BEOL) processes. In some other embodiments, as illustrated in FIG. 8B, the second switch 134A of the first node or switch circuit 130A includes a thin film transistor (TFT) fabricated by Back-End-of Line (BEOL) processes. In some embodiments, the second switch 134A of the first node or switch circuit 130A is a n-type MOSFET. In some alternative embodiments, the second switch 134A of the first node or switch circuit 130A is a p-type MOSFET.

As illustrated in FIG. 1, FIG. 2A and FIG. 2B, the resistor 100 may further include a second spare resistor wiring 120B, a second node or switch circuit 130B and a third spare resistor wiring 120C. The second spare resistor wiring 120B includes a first end and a second end opposite to the first end, wherein the first end of the second spare resistor wiring 120B is electrically connected to the second node or switch circuit 130B, and the second end of the second spare resistor wiring 120B is electrically connected to the first node or switch circuit 130A. The first spare resistor wiring 120A and the second spare resistor wiring 120B may be arranged along a second ring-shaped layout path (e.g., an octagonal ring-shaped layout path or other suitable types of ring-shaped layout path), wherein the first spare resistor wiring 120A is distributed in a bottom region of the second ring-shaped layout path, and the second spare resistor wiring 120B is distributed in an upper region of the second ring-shaped layout path. The first spare resistor wiring 120A and the second spare resistor wiring 120B may be substantially identical or different in resistance. The first spare resistor wiring 120A and the second spare resistor wiring 120B may be made from same material or different materials. The first spare resistor wiring 120A and the second spare resistor wiring 120B are substantially identical or different in linewidth, the length and/or the thickness. Through properly control of the linewidth, the length and/or the thickness, desired resistance of the first spare resistor wiring 120A and the second spare resistor wiring 120B can be obtained. For example, as illustrated in FIG. 1, the first spare resistor wiring 120A and the second spare resistor wiring 120B are made from the same ultra-thin metallic material (e.g., copper or alloys thereof), and the first spare resistor wiring 120A and the second spare resistor wiring 120B are substantially identical in linewidth, the length and the thickness. Furthermore, the length of the first spare resistor wiring 120A and the second spare resistor wiring 120B is less than the length of the first resistor wiring 110A and the second resistor wiring 110B, as illustrated in FIG. 1. The width of the second spare resistor wiring 120B may range from about 1.5 micrometers to about 2.5 micrometers, the thickness of the second spare resistor wiring 120B may range from about 2 micrometers to about 10 micrometers, and the ratio of the width of the second spare resistor wiring 120B to the thickness the second spare resistor wiring 120B may range from about 0.18 to about 1.25. The width of the third spare resistor wiring 120C may range from about 1.5 micrometers to about 2.5 micrometers, the thickness of the third spare resistor wiring 120C may range from about 2 micrometers to about 10 micrometers, the ratio of the width of the third spare resistor wiring 120C to the thickness the third spare resistor wiring 120C may range from about 0.18 to about 1.25. The spacing between the second spare resistor wiring 120B and the first spare resistor wiring 120A may range from about 0.5 micrometers to about 2 micrometers. The spacing between the second spare resistor wiring 120B and the third spare resistor wiring 120C may range from about 0.5 micrometers to about 2 micrometers. Furthermore, the ratio of the width of the second spare resistor wiring 120B or the third spare resistor wiring 120C to the spacing between the second spare resistor wiring 120B and the first spare resistor wiring 120A or the spacing between the second spare resistor wiring 120B and the third spare resistor wiring 120C may range from about 0.75 to about 5.

As illustrated in FIG. 2A, the second end of the second spare resistor wiring 120B is electrically connected to the second resistor wiring 110B through a third switch 136A (e.g., a third transistor) of the first node or switch circuit 130A. The second spare resistor wiring 120B and the second resistor wiring 110B are electrically connected to source/drain electrodes of the third switch 136A, respectively. The electrical connection between the second spare resistor wiring 120B and the second resistor wiring 110B is determined by the state of the third switch 136A of the first node or switch circuit 130A. In other words, the second spare resistor wiring 120B and the second resistor wiring 110B are electrically connected in series by the third switch 136A of the first node or switch circuit 130A when the third switch 136A is turned-on or enabled. In some embodiments, as illustrated in FIG. 8A, the third switch 136A of the first node or switch circuit 130A includes a metal-oxide-semiconductor field effect transistor (MOSFET) fabricated by Front-End-of Line (FEoL) processes. In some other embodiments, as illustrated in FIG. 8B, the third switch 136A of the first node or switch circuit 130A includes a thin film transistor (TFT) fabricated by Back-End-of Line (BEOL) processes. In some embodiments, the third switch 136A of the first node or switch circuit 130A is a n-type MOSFET. In some alternative embodiments, the third switch 136A of the first node or switch circuit 130A is a p-type MOSFET.

As illustrated in FIG. 2B, the first spare resistor wiring 120A is electrically connected to the first end of the second spare resistor wiring 120B through a first switch 132B (e.g., a first transistor) of the second node or switch circuit 130B. The first spare resistor wiring 120A and the second spare resistor wiring 120B are electrically connected to source/drain electrodes of the first switch 132B, respectively. The electrical connection between the first spare resistor wiring 120A and the second spare resistor wiring 120B is determined by the state of the first switch 132B of the second node or switch circuit 130B. In other words, the first spare resistor wiring 120A and the second spare resistor wiring 120B are electrically connected in series by the first switch 132B of the second node or switch circuit 130B when the first switch 132B is turned-on or enabled. In some embodiments, as illustrated in FIG. 8A, the first switch 132B of the second node or switch circuit 130B includes a metal-oxide-semiconductor field effect transistor (MOSFET) fabricated by Front-End-of Line (FEOL) processes. In some other embodiments, as illustrated in FIG. 8B, the first switch 132B of the second node or switch circuit 130B includes a thin film transistor (TFT) fabricated by Back-End-of Line (BEOL) processes. In some embodiments, the first switch 132B of the second node or switch circuit 130B is a n-type MOSFET. In some alternative embodiments, the first switch 132B of the second node or switch circuit 130B is a p-type MOSFET.

The first spare resistor wiring 120A is electrically connected to the third spare resistor wiring 120C through a second switch 134B (e.g., a second transistor) of the second node or switch circuit 130B. The first spare resistor wiring 120A and the third spare resistor wiring 120C are electrically connected to source/drain electrodes of the second switch 134B, respectively. The electrical connection between the first spare resistor wiring 120A and the third spare resistor wiring 120C is determined by the state of the second switch 134B of the second node or switch circuit 130B. In other words, the first spare resistor wiring 120A and the third spare resistor wiring 120C are electrically connected in series by the second switch 134B of the second node or switch circuit 130B when the second switch 134B is turned-on or enabled. In some embodiments, as illustrated in FIG. 8A, the second switch 134B of the second node or switch circuit 130B includes a metal-oxide-semiconductor field effect transistor (MOSFET) fabricated by Front-End-of Line (FEOL) processes. In some other embodiments, as illustrated in FIG. 8B, the second switch 134B of the second node or switch circuit 130B includes a thin film transistor (TFT) fabricated by Back-End-of Line (BEOL) processes. In some embodiments, the second switch 134B of the second node or switch circuit 130B is a n-type MOSFET. In some alternative embodiments, the second switch 134B of the second node or switch circuit 130B is a p-type MOSFET.

As illustrated in FIG. 1, FIG. 2B and FIG. 2C, the resistor 100 may further include a fourth spare resistor wiring 120D, a third node or switch circuit 130C and a fifth spare resistor wiring 120E. The fourth spare resistor wiring 120D includes a first end and a second end opposite to the first end, wherein the first end of the fourth spare resistor wiring 120D is electrically connected to the second node or switch circuit 130B, and the second end of the fourth spare resistor wiring 120D is electrically connected to the third node or switch circuit 130C. The third spare resistor wiring 120C and the fourth spare resistor wiring 120D may be arranged along a third ring-shaped layout path (e.g., an octagonal ring-shaped layout path or other suitable types of ring-shaped layout path), wherein the third spare resistor wiring 120C is distributed in an upper region of the third ring-shaped layout path, and the fourth spare resistor wiring 120D is distributed in a bottom region of the third ring-shaped layout path. The third spare resistor wiring 120C and the fourth spare resistor wiring 120D may be substantially identical or different in resistance. The third spare resistor wiring 120C and the fourth spare resistor wiring 120D may be made from same material or different materials. The third spare resistor wiring 120C and the fourth spare resistor wiring 120D are substantially identical or different in linewidth, the length and/or the thickness. Through properly control of the linewidth, the length and/or the thickness, desired resistance of the third spare resistor wiring 120C and the fourth spare resistor wiring 120D can be obtained. For example, as illustrated in FIG. 1, the third spare resistor wiring 120C and the fourth spare resistor wiring 120D are made from the same ultra-thin metallic material (e.g., copper or alloys thereof), and the third spare resistor wiring 120C and the fourth spare resistor wiring 120D are substantially identical in linewidth, the length and the thickness. Furthermore, the length of the third spare resistor wiring 120C and the fourth spare resistor wiring 120D is less than the length of the first spare resistor wiring 120A and the second spare resistor wiring 120B, as illustrated in FIG. 1. The width of the fourth spare resistor wiring 120D may range from about 1.5 micrometers to about 2.5 micrometers, the thickness of the fourth spare resistor wiring 120D may range from about 2 micrometers to about 10 micrometers, and the ratio of the width of the fourth spare resistor wiring 120D to the thickness the fourth spare resistor wiring 120D may range from about 0.18 to about 1.25. The width of the fifth spare resistor wiring 120E may range from about 1.5 micrometers to about 2.5 micrometers, the thickness of the fifth spare resistor wiring 120E may range from about 2 micrometers to about 10 micrometers, the ratio of the width of the fifth spare resistor wiring 120E to the thickness the fifth spare resistor wiring 120E may range from about 0.18 to about 1.25. The spacing between the fourth spare resistor wiring 120D and the first spare resistor wiring 120A may range from about 0.5 micrometers to about 2 micrometers. The spacing between the fourth spare resistor wiring 120D and the fifth spare resistor wiring 120E may range from about 0.5 micrometers to about 2 micrometers. Furthermore, the ratio of the width of the fourth spare resistor wiring 120D or the fifth spare resistor wiring 120E to the spacing between the fourth spare resistor wiring 120D and the first spare resistor wiring 120A or the spacing between the fourth spare resistor wiring 120D and the fifth spare resistor wiring 120E may range from about 0.75 to about 5.

As illustrated in FIG. 2B, the second spare resistor wiring 120B is electrically connected to the first end of the fourth spare resistor wiring 120D through a third switch 136A (e.g., a third transistor) of the second node or switch circuit 130B. The second spare resistor wiring 120B and the fourth spare resistor wiring 120D are electrically connected to source/drain electrodes of the third switch 136B, respectively. The electrical connection between the second spare resistor wiring 120B and the fourth spare resistor wiring 120D is determined by the state of the third switch 136B of the second node or switch circuit 130B. In other words, the second spare resistor wiring 120B and the fourth spare resistor wiring 120D are electrically connected in series by the third switch 136B of the second node or switch circuit 130B when the third switch 136B is turned-on or enabled. In some embodiments, as illustrated in FIG. 8A, the third switch 136B of the second node or switch circuit 130B includes a metal-oxide-semiconductor field effect transistor (MOSFET) fabricated by Front-End-of Line (FEOL) processes. In some other embodiments, as illustrated in FIG. 8B, the third switch 136B of the second node or switch circuit 130B includes a thin film transistor (TFT) fabricated by Back-End-of Line (BEOL) processes. In some embodiments, the third switch 136B of the second node or switch circuit 130B is a n-type MOSFET. In some alternative embodiments, the third switch 136B of the second node or switch circuit 130B is a p-type MOSFET.

As illustrated in FIG. 2C, the third spare resistor wiring 120C is electrically connected to the second end of the fourth spare resistor wiring 120D through a first switch 132C (e.g., a first transistor) of the third node or switch circuit 130C. The third spare resistor wiring 120C and the fourth spare resistor wiring 120D are electrically connected to source/drain electrodes of the first switch 132C, respectively. The electrical connection between the third spare resistor wiring 120C and the fourth spare resistor wiring 120D is determined by the state of the first switch 132C of the third node or switch circuit 130C. In other words, the third spare resistor wiring 120C and the fourth spare resistor wiring 120D are electrically connected in series by the first switch 132C of the third node or switch circuit 130C when the first switch 132C is turned-on or enabled. In some embodiments, as illustrated in FIG. 8A, the first switch 132C of the third node or switch circuit 130C includes a metal-oxide-semiconductor field effect transistor (MOSFET) fabricated by Front-End-of Line (FEOL) processes. In some other embodiments, as illustrated in FIG. 8B, the first switch 132C of the third node or switch circuit 130C includes a thin film transistor (TFT) fabricated by Back-End-of Line (BEoL) processes. In some embodiments, the first switch 132C of the third node or switch circuit 130C is a n-type MOSFET. In some alternative embodiments, the first switch 132C of the third node or switch circuit 130C is a p-type MOSFET.

The third spare resistor wiring 120C is electrically connected to the fifth spare resistor wiring 120E through a second switch 134C (e.g., a second transistor) of the third node or switch circuit 130C. The third spare resistor wiring 120C and the fifth spare resistor wiring 120E are electrically connected to source/drain electrodes of the second switch 134C, respectively. The electrical connection between the third spare resistor wiring 120C and the fifth spare resistor wiring 120E is determined by the state of the second switch 134C of the third node or switch circuit 130C. In other words, the third spare resistor wiring 120C and the fifth spare resistor wiring 120E are electrically connected in series by the second switch 134C of the third node or switch circuit 130C when the second switch 134C is turned-on or enabled. In some embodiments, as illustrated in FIG. 8A, the second switch 134C of the third node or switch circuit 130C includes a metal-oxide-semiconductor field effect transistor (MOSFET) fabricated by Front-End-of Line (FEOL) processes. In some other embodiments, as illustrated in FIG. 8B, the second switch 134C of the third node or switch circuit 130C includes a thin film transistor (TFT) fabricated by Back-End-of Line (BEOL) processes. In some embodiments, the second switch 134C of the third node or switch circuit 130C is a n-type MOSFET. In some alternative embodiments, the second switch 134C of the third node or switch circuit 130C is a p-type MOSFET.

As illustrated in FIG. 1, FIG. 2C and FIG. 2D, the resistor 100 may further include a sixth spare resistor wiring 120F, a fourth node or switch circuit 130D and a seventh spare resistor wiring 120G. The sixth spare resistor wiring 120F includes a first end and a second end opposite to the first end, wherein the first end of the sixth spare resistor wiring 120F is electrically connected to the third node or switch circuit 130C, and the second end of the sixth spare resistor wiring 120F is electrically connected to the fourth node or switch circuit 130D. The fifth spare resistor wiring 120E and the sixth spare resistor wiring 120F may be arranged along a fourth ring-shaped layout path (e.g., an octagonal ring-shaped layout path or other suitable types of ring-shaped layout path), wherein the fifth spare resistor wiring 120E is distributed in a bottom region of the fourth ring-shaped layout path, and the sixth spare resistor wiring 120F is distributed in an upper region of the fourth ring-shaped layout path. The fifth spare resistor wiring 120E and the sixth spare resistor wiring 120F may be substantially identical or different in resistance. The fifth spare resistor wiring 120E and the sixth spare resistor wiring 120F may be made from same material or different materials. The fifth spare resistor wiring 120E and the sixth spare resistor wiring 120F are substantially identical or different in linewidth, the length and/or the thickness. Through properly control of the linewidth, the length and/or the thickness, desired resistance of the fifth spare resistor wiring 120E and the sixth spare resistor wiring 120F can be obtained. For example, as illustrated in FIG. 1, the fifth spare resistor wiring 120E and the sixth spare resistor wiring 120F are made from the same ultra-thin metallic material (e.g., copper or alloys thereof), and the fifth spare resistor wiring 120E and the sixth spare resistor wiring 120F are substantially identical in linewidth, the length and the thickness. Furthermore, the length of the fifth spare resistor wiring 120E and the sixth spare resistor wiring 120F is less than the length of the third spare resistor wiring 120C and the fourth spare resistor wiring 120D, as illustrated in FIG. 1. The width of the sixth spare resistor wiring 120F may range from about 1.5 micrometers to about 2.5 micrometers, the thickness of the sixth spare resistor wiring 120F may range from about 2 micrometers to about 10 micrometers, and the ratio of the width of the sixth spare resistor wiring 120F to the thickness the sixth spare resistor wiring 120F may range from about 0.18 to about 1.25. The width of the seventh spare resistor wiring 120G may range from about 1.5 micrometers to about 2.5 micrometers, the thickness of the seventh spare resistor wiring 120G may range from about 2 micrometers to about 10 micrometers, the ratio of the width of the seventh spare resistor wiring 120G to the thickness the seventh spare resistor wiring 120G may range from about 0.18 to about 1.25. The spacing between the sixth spare resistor wiring 120F and the seventh spare resistor wiring 120G may range from about 0.5 micrometers to about 2 micrometers. The spacing between the sixth spare resistor wiring 120F and the third spare resistor wiring 120C may range from about 0.5 micrometers to about 2 micrometers. The spacing between the seventh spare resistor wiring 120G and the fifth spare resistor wiring 120E may range from about 0.5 micrometers to about 2 micrometers. Furthermore, the ratio of the width of the sixth spare resistor wiring 120F or the seventh spare resistor wiring 120G to the spacing between the sixth spare resistor wiring 120F and the seventh spare resistor wiring 120G, the spacing between the sixth spare resistor wiring 120F and the third spare resistor wiring 120C or the spacing between the seventh spare resistor wiring 120G and the fifth spare resistor wiring 120E may range from about 0.75 to about 5.

As illustrated in FIG. 2C, the fourth spare resistor wiring 120D is electrically connected to the first end of the sixth spare resistor wiring 120F through a third switch 136C (e.g., a third transistor) of the third node or switch circuit 130C. The fourth spare resistor wiring 120D and the sixth spare resistor wiring 120F are electrically connected to source/drain electrodes of the third switch 136C, respectively. The electrical connection between the fourth spare resistor wiring 120D and the sixth spare resistor wiring 120F is determined by the state of the third switch 136C of the third node or switch circuit 130C. In other words, the fourth spare resistor wiring 120D and the sixth spare resistor wiring 120F are electrically connected in series by the third switch 136C of the third node or switch circuit 130C when the third switch 136C is turned-on or enabled. In some embodiments, as illustrated in FIG. 8A, the third switch 136C of the third node or switch circuit 130C includes a metal-oxide-semiconductor field effect transistor (MOSFET) fabricated by Front-End-of Line (FEOL) processes. In some other embodiments, as illustrated in FIG. 8B, the third switch 136C of the third node or switch circuit 130C includes a thin film transistor (TFT) fabricated by Back-End-of Line (BEOL) processes. In some embodiments, the third switch 136C of the third node or switch circuit 130C is a n-type MOSFET. In some alternative embodiments, the third switch 136C of the third node or switch circuit 130C is a p-type MOSFET.

As illustrated in FIG. 2D, the fifth spare resistor wiring 120E is electrically connected to the second end of the sixth spare resistor wiring 120F through a first switch 132D (e.g., a first transistor) of the fourth node or switch circuit 130D. The fifth spare resistor wiring 120E and the sixth spare resistor wiring 120F are electrically connected to source/drain electrodes of the first switch 132D, respectively. The electrical connection between the fifth spare resistor wiring 120E and the sixth spare resistor wiring 120F is determined by the state of the first switch 132D of the fourth node or switch circuit 130D. In other words, the fifth spare resistor wiring 120E and the sixth spare resistor wiring 120F are electrically connected in series by the first switch 132D of the fourth node or switch circuit 130D when the first switch 132D is turned-on or enabled. In some embodiments, as illustrated in FIG. 8A, the first switch 132D of the fourth node or switch circuit 130D includes a metal-oxide-semiconductor field effect transistor (MOSFET) fabricated by Front-End-of Line (FEOL) processes. In some other embodiments, as illustrated in FIG. 8B, the first switch 132D of the fourth node or switch circuit 130D includes a thin film transistor (TFT) fabricated by Back-End-of Line (BEOL) processes. In some embodiments, the first switch 132D of the fourth node or switch circuit 130D is a n-type MOSFET. In some alternative embodiments, the first switch 132D of the fourth node or switch circuit 130D is a p-type MOSFET.

The fifth spare resistor wiring 120E is electrically connected to a first end of the seventh spare resistor wiring 120G through a second switch 134D (e.g., a second transistor) of the fourth node or switch circuit 130D. The fifth spare resistor wiring 120E and the first end of the seventh spare resistor wiring 120G are electrically connected to source/drain electrodes of the second switch 134D, respectively. The electrical connection between the fifth spare resistor wiring 120E and the first end of the seventh spare resistor wiring 120G is determined by the state of the second switch 134D of the fourth node or switch circuit 130D. In other words, the fifth spare resistor wiring 120E and the seventh spare resistor wiring 120G are electrically connected in series by the second switch 134D of the fourth node or switch circuit 130D when the second switch 134D is turned-on or enabled. In some embodiments, as illustrated in FIG. 8A, the second switch 134D of the fourth node or switch circuit 130D includes a metal-oxide-semiconductor field effect transistor (MOSFET) fabricated by Front-End-of Line (FEOL) processes. In some other embodiments, as illustrated in FIG. 8B, the second switch 134D of the fourth node or switch circuit 130D includes a thin film transistor (TFT) fabricated by Back-End-of Line (BEOL) processes. In some embodiments, the second switch 134D of the fourth node or switch circuit 130D is a n-type MOSFET. In some alternative embodiments, the second switch 134D of the fourth node or switch circuit 130D is a p-type MOSFET.

As illustrated in FIG. 2D, the seventh spare resistor wiring 120G may be arranged along a fifth ring-shaped layout path (e.g., an octagonal ring-shaped layout path or other suitable types of ring-shaped layout path). The seventh spare resistor wiring 120G includes a first end electrically connected to the fifth spare resistor wiring 120E through the second switch 134D (e.g., a second transistor) of the fourth node or switch circuit 130D, and the seventh spare resistor wiring 120G further includes a second end electrically connected to the sixth spare resistor wiring 120F through a third switch 136D (e.g., a second transistor) of the fourth node or switch circuit 130D.

The second end of the seventh spare resistor wiring 120G and the sixth spare resistor wiring 120F are electrically connected to source/drain electrodes of the third switch 136C, respectively. The electrical connection between the second end of the seventh spare resistor wiring 120G and the sixth spare resistor wiring 120F is determined by the state of the third switch 136D of the fourth node or switch circuit 130D. In other words, the seventh spare resistor wiring 120G and the sixth spare resistor wiring 120F are electrically connected in series by the third switch 136D of the fourth node or switch circuit 130D when the third switch 136D is turned-on or enabled. In some embodiments, as illustrated in FIG. 8A, the third switch 136D of the fourth node or switch circuit 130D includes a metal-oxide-semiconductor field effect transistor (MOSFET) fabricated by Front-End-of Line (FEOL) processes. In some other embodiments, as illustrated in FIG. 8B, the third switch 136D of the fourth node or switch circuit 130D includes a thin film transistor (TFT) fabricated by Back-End-of Line (BEOL) processes. In some embodiments, the third switch 136D of the fourth node or switch circuit 130D is a n-type MOSFET. In some alternative embodiments, the third switch 136D of the fourth node or switch circuit 130D is a p-type MOSFET.

Referring back to FIG. 1, an area surrounded by the first ring-shaped layout path is greater than an area surrounded by the second ring-shaped layout path (i.e. the first ring-shaped layout path is longer than the second ring-shaped layout path), the area surrounded by the second ring-shaped layout path is greater than an area surrounded by the third ring-shaped layout path (i.e. the second ring-shaped layout path is longer than the third ring-shaped layout path), the area surrounded by the third ring-shaped layout path is greater than an area surrounded by the fourth ring-shaped layout path (i.e. the third ring-shaped layout path is longer than the fourth ring-shaped layout path), and the area surrounded by the fourth ring-shaped layout path is greater than an area surrounded by the fifth ring-shaped layout path (i.e. the fourth ring-shaped layout path is longer than the fifth ring-shaped layout path). In some embodiments, the first resistor wiring 110A and the second resistor wiring 110B arranged along a first ring-shaped layout path, the first spare resistor wiring 120A and the second spare resistor wiring 120B arranged along the second ring-shaped layout path, the third spare resistor wiring 120C and the fourth spare resistor wiring 120D arranged along the third ring-shaped layout path, the fifth spare resistor wiring 120E and the sixth spare resistor wiring 120F arranged along the fourth ring-shaped layout path, and the seventh spare resistor wiring 120G arranged along a fifth ring-shaped layout path may be substantially identical in thickness and/or width. In some other embodiments, the first resistor wiring 110A and the second resistor wiring 110B arranged along a first ring-shaped layout path, the first spare resistor wiring 120A and the second spare resistor wiring 120B arranged along the second ring-shaped layout path, the third spare resistor wiring 120C and the fourth spare resistor wiring 120D arranged along the third ring-shaped layout path, the fifth spare resistor wiring 120E and the sixth spare resistor wiring 120F arranged along the fourth ring-shaped layout path, and the seventh spare resistor wiring 120G arranged along a fifth ring-shaped layout path may be different in thickness and/or width. Accordingly, the first resistor wiring 110A and the second resistor wiring 110B arranged along a first ring-shaped layout path, the first spare resistor wiring 120A and the second spare resistor wiring 120B arranged along the second ring-shaped layout path, the third spare resistor wiring 120C and the fourth spare resistor wiring 120D arranged along the third ring-shaped layout path, the fifth spare resistor wiring 120E and the sixth spare resistor wiring 120F arranged along the fourth ring-shaped layout path, and the seventh spare resistor wiring 120G arranged along a fifth ring-shaped layout path may have substantially identical resistance or may be different in resistance.

In some embodiments, as illustrated in FIG. 1, the first spare resistor wiring 120A is between the second resistor wiring 110B and the fourth spare resistor wiring 120D, the second spare resistor wiring 120B is between the first resistor wiring 110A and the third spare resistor wiring 120C, the third spare resistor wiring 120C is between the second spare resistor wiring 120B and the sixth spare resistor wiring 120F, the fourth spare resistor wiring 120D is between the first spare resistor wiring 120A and the fifth spare resistor wiring 120E, the fifth spare resistor wiring 120E is between the fourth spare resistor wiring 120D and the seventh spare resistor wiring 120G, the sixth spare resistor wiring 120F is between the third spare resistor wiring 120C and the seventh spare resistor wiring 120G.

The first resistor wiring 110A, the second resistor wiring 110B, the first spare resistor wiring 120A, the second spare resistor wiring 120B, the third spare resistor wiring 120C, the fourth spare resistor wiring 120D, the fifth spare resistor wiring 120E and the sixth spare resistor wiring 120F are distributed outside an area surrounded by the seventh spare resistor 120G. In some embodiments, the first spare resistor wiring 120A, the second spare resistor wiring 120B, the third spare resistor wiring 120C, the fourth spare resistor wiring 120D, the fifth spare resistor wiring 120E, the sixth spare resistor wiring 120F and the seven spare resistor wiring 120G are distributed in an area surrounded by the first resistor wiring 110A and the second resistor wiring 110B.

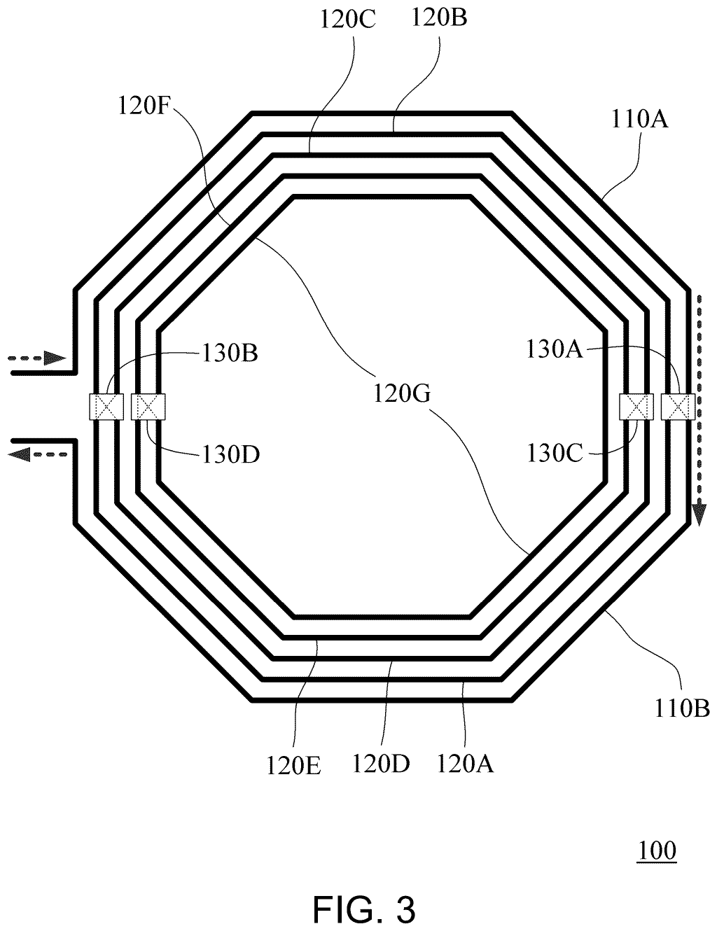

The state of the switches 132A, 134A, 136A, 132B, 134B, 136B, 132C, 134C, 136C, 132D, 134D and 136D (shown in FIG. 2A through FIG. 2D) can be controlled independently. Through properly control of the state of the switches 132A, 134A, 136A, 132B, 134B, 136B, 132C, 134C, 136C, 132D, 134D and 136D, resistance of the variable resistor 100 (shown in FIG. 3) can be electronically modulated. Various operation modes will be described in accompany with FIG. 3 through FIG. 7.

FIG. 3 schematically illustrate a top view of the variable resistor 100 operated in an operation mode in accordance with the first embodiment of the disclosure.

Referring to FIG. 2A through FIG. 2D as well as FIG. 3, the first switch 132A of the first node or switch circuit 130A is turned-on or enabled, and the rest of the switches (i.e., the second switch 134A of the first node or switch circuit 130A, the third switch 136A of the first node or switch circuit 130A, the first switch 132B of the second node or switch circuit 130B, the second switch 134B of the second node or switch circuit 130B, the third switch 136B of the second node or switch circuit 130B, the first switch 132C of the third node or switch circuit 130C, the second switch 134C of the third node or switch circuit 130C, the third switch 136C of the third node or switch circuit 130C, the first switch 132D of the fourth node or switch circuit 130D, the second switch 134D of the fourth node or switch circuit 130D, and the third switch 136D of the fourth node or switch circuit 130D) are turned-off or disabled. Under such operation mode, the first resistor wiring 110A and the second resistor wiring 110B are electrically connected in series by the first switch 132A of the first node or switch circuit 130A. The first spare resistor wiring 120A, the second spare resistor wiring 120B, the third spare resistor wiring 120C, the fourth spare resistor wiring 120D, the fifth spare resistor wiring 120E, the sixth spare resistor wiring 120F and the seventh spare resistor wiring 120G are electrically insulated from the first resistor wiring 110A and the second resistor wiring 110B.

Under such operation mode, when a current is applied from the current input end of the first resistor wiring 110A, flows through the first resistor wiring 110A and the second resistor wiring 110B of the variable resistor 100, and outputs from the current input end of the second resistor wiring 110B, the variable resistor 100 provides a resistance about (R1+R2) Ohm, where R1 represents the resistance of the first resistor wiring 110A, and R2 represents the resistance of the second resistor wiring 110B.

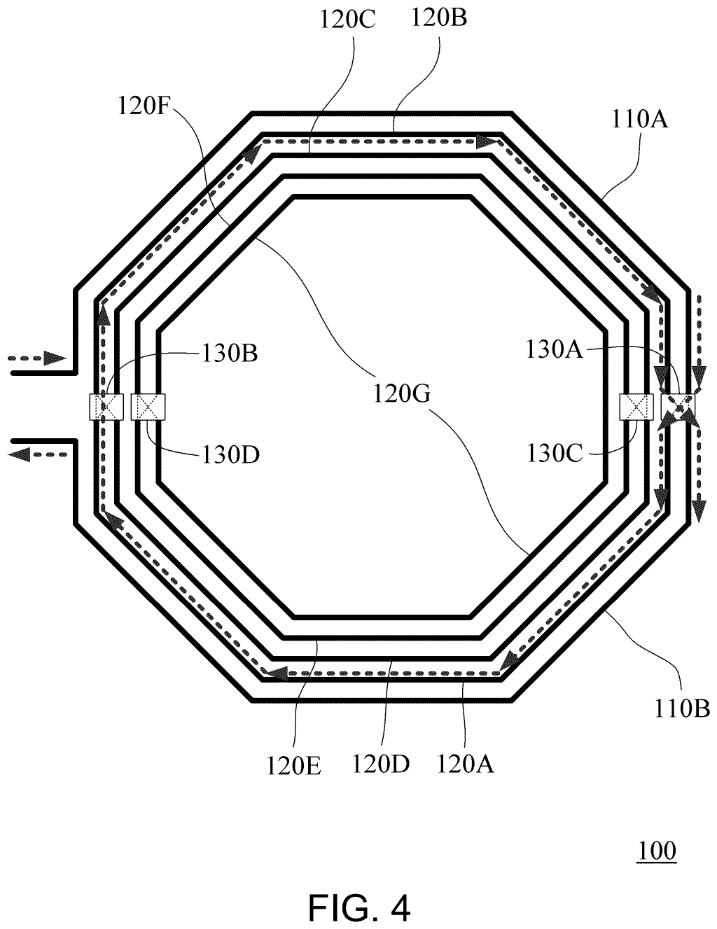

FIG. 4 schematically illustrate a top view of the variable resistor 100 operated in an operation mode in accordance with the second embodiment of the disclosure.

Referring to FIG. 2A through FIG. 2D as well as FIG. 4, the second switch 134A of the first node or switch circuit 130A, the third switch 136A of the first node or switch circuit 130A and the first switch 132B of the second node or switch circuit 130B are turned-on or enabled, and the rest of the switches (i.e., the first switch 132A of the first node or switch circuit 130A, the second switch 134B of the second node or switch circuit 130B, the third switch 136B of the second node or switch circuit 130B, the first switch 132C of the third node or switch circuit 130C, the second switch 134C of the third node or switch circuit 130C, the third switch 136C of the third node or switch circuit 130C, the first switch 132D of the fourth node or switch circuit 130D, the second switch 134D of the fourth node or switch circuit 130D, and the third switch 136D of the fourth node or switch circuit 130D) are turned-off or disabled. Under such operation mode, the first resistor wiring 110A, the first spare resistor wiring 120A, the second spare resistor wiring 120B and the second resistor wiring 110B are electrically connected in series by the second switch 134A of the first node or switch circuit 130A, the third switch 136A of the first node or switch circuit 130A and the first switch 132B of the second node or switch circuit 130B. The third spare resistor wiring 120C, the fourth spare resistor wiring 120D, the fifth spare resistor wiring 120E, the sixth spare resistor wiring 120F and the seventh spare resistor wiring 120G are electrically insulated from the first resistor wiring 110A, the second resistor wiring 110B, the first spare resistor wiring 120A and the second spare resistor wiring 120B.

Under such operation mode, when a current is applied from the current input end of the first resistor wiring 110A, flows through the first resistor wiring 110A, the first spare resistor wiring 120A, the second spare resistor wiring 120B and the second resistor wiring 110B of the variable resistor 100, and outputs from the current input end of the second resistor wiring 110B, the variable resistor 100 provides a resistance about (R1+R1′+R2′+R2) Ohm, where R1 represents the resistance of the first resistor wiring 110A, R1′ represents the resistance of the first spare resistor wiring 120A, R2 represents the resistance of the second resistor wiring 110B, and R2′ represents the resistance of the second spare resistor wiring 120B.

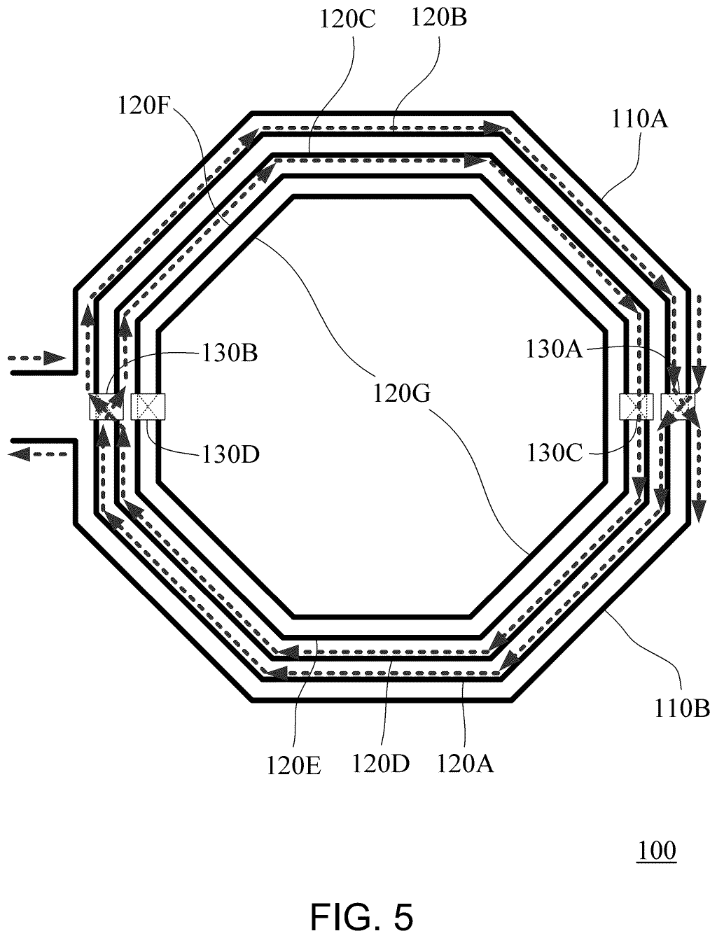

FIG. 5 schematically illustrate a top view of the variable resistor 100 operated in an operation mode in accordance with the third embodiment of the disclosure.

Referring to FIG. 2A through FIG. 2D as well as FIG. 5, the second switch 134A of the first node or switch circuit 130A, the third switch 136A of the first node or switch circuit 130A, the second switch 134B of the second node or switch circuit 130B, the third switch 136B of the second node or switch circuit 130B and the first switch 132C of the third node or switch circuit 130C are turned-on or enabled, and the rest of the switches (i.e., the first switch 132A of the first node or switch circuit 130A, the first switch 132B of the second node or switch circuit 130B, the second switch 134C of the third node or switch circuit 130C, the third switch 136C of the third node or switch circuit 130C, the first switch 132D of the fourth node or switch circuit 130D, the second switch 134D of the fourth node or switch circuit 130D, and the third switch 136D of the fourth node or switch circuit 130D) are turned-off or disabled. Under such operation mode, the first resistor wiring 110A, the first spare resistor wiring 120A, the third spare resistor wiring 120C, the fourth spare resistor wiring 120D, the second spare resistor wiring 120B and the second resistor wiring 110B are electrically connected in series by the second switch 134A of the first node or switch circuit 130A, the third switch 136A of the first node or switch circuit 130A, the second switch 134B of the second node or switch circuit 130B, the third switch 136B of the second node or switch circuit 130B and the first switch 132C of the third node or switch circuit 130C. The fifth spare resistor wiring 120E, the sixth spare resistor wiring 120F and the seventh spare resistor wiring 120G are electrically insulated from the first resistor wiring 110A, the first spare resistor wiring 120A, the third spare resistor wiring 120C, the fourth spare resistor wiring 120D, the second spare resistor wiring 120B and the second resistor wiring 110B.

Under such operation mode, when a current is applied from the current input end of the first resistor wiring 110A, flows through the first resistor wiring 110A, the first spare resistor wiring 120A, the third spare resistor wiring 120C, the fourth spare resistor wiring 120D, the second spare resistor wiring 120B and the second resistor wiring 110B of the variable resistor 100, and outputs from the current input end of the second resistor wiring 110B, the variable resistor 100 provides a resistance about (R1+R1′+R3′+R4′+R2′+R2) Ohm, where R1 represents the resistance of the first resistor wiring 110A, R1′ represents the resistance of the first spare resistor wiring 120A, R2 represents the resistance of the second resistor wiring 110B, R2′ represents the resistance of the second spare resistor wiring 120B, R3′ represents the resistance of the third resistor wiring 110C, and R4′ represents the resistance of the fourth resistor wiring 110D.

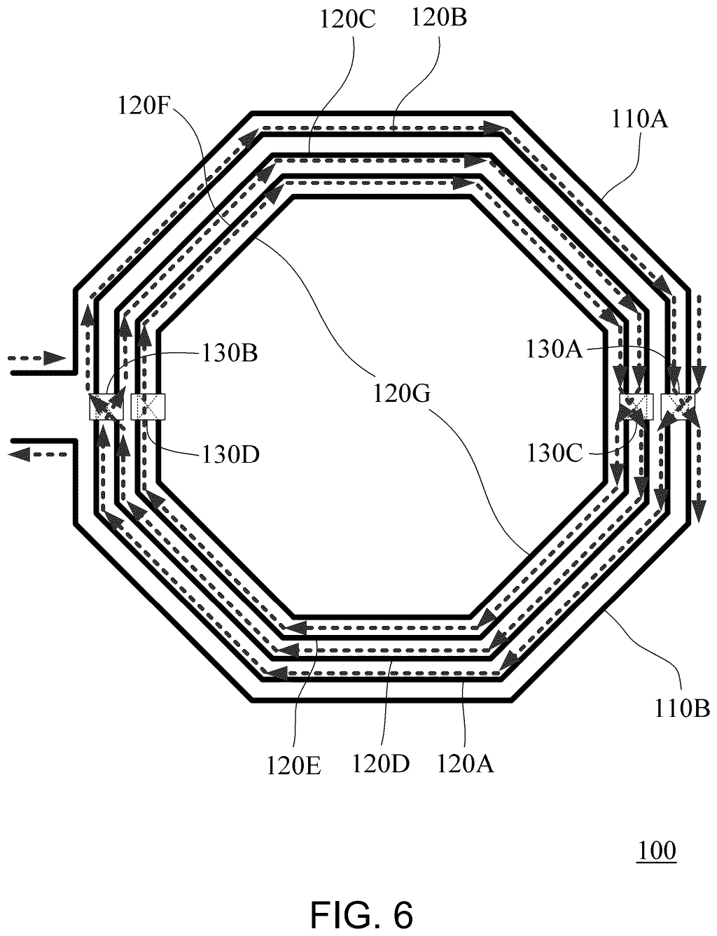

FIG. 6 schematically illustrate a top view of the variable resistor 100 operated in an operation mode in accordance with the fourth embodiment of the disclosure.

Referring to FIG. 2A through FIG. 2D as well as FIG. 6, the second switch 134A of the first node or switch circuit 130A, the third switch 136A of the first node or switch circuit 130A, the second switch 134B of the second node or switch circuit 130B, the third switch 136B of the second node or switch circuit 130B, the second switch 134C of the third node or switch circuit 130C, the third switch 136C of the third node or switch circuit 130C and the first switch 132D of the fourth node or switch circuit 130D are turned-on or enabled, and the rest of the switches (i.e., the first switch 132A of the first node or switch circuit 130A, the first switch 132B of the second node or switch circuit 130B, the first switch 132C of the third node or switch circuit 130C, the second switch 134D of the fourth node or switch circuit 130D, and the third switch 136D of the fourth node or switch circuit 130D) are turned-off or disabled. Under such operation mode, the first resistor wiring 110A, the first spare resistor wiring 120A, the third spare resistor wiring 120C, the fifth spare resistor wiring 120E, the sixth spare resistor wiring 120F, the fourth spare resistor wiring 120D, the second spare resistor wiring 120B and the second resistor wiring 110B are electrically connected in series by the second switch 134A of the first node or switch circuit 130A, the third switch 136A of the first node or switch circuit 130A, the second switch 134B of the second node or switch circuit 130B, the third switch 136B of the second node or switch circuit 130B, the second switch 134C of the third node or switch circuit 130C, the third switch 136C of the third node or switch circuit 130C and the first switch 132D of the fourth node or switch circuit 130D. The seventh spare resistor wiring 120G is electrically insulated from the first resistor wiring 110A, the first spare resistor wiring 120A, the third spare resistor wiring 120C, the fifth spare resistor wiring 120E, the sixth spare resistor wiring 120F, the fourth spare resistor wiring 120D, the second spare resistor wiring 120B and the second resistor wiring 110B.

Under such operation mode, when a current is applied from the current input end of the first resistor wiring 110A, flows through the first resistor wiring 110A, the first spare resistor wiring 120A, the third spare resistor wiring 120C, the fifth spare resistor wiring 120E, the sixth spare resistor wiring 120F, the fourth spare resistor wiring 120D, the second spare resistor wiring 120B and the second resistor wiring 110B of the variable resistor 100, and outputs from the current input end of the second resistor wiring 110B, the variable resistor 100 provides a resistance about (R1+R1′+R3′+R5′+R6′+R4′+R2′+R2) Ohm, where R1 represents the resistance of the first resistor wiring 110A, R1′ represents the resistance of the first spare resistor wiring 120A, R2 represents the resistance of the second resistor wiring 110B, R2′ represents the resistance of the second spare resistor wiring 120B, R3′ represents the resistance of the third resistor wiring 110C, R4′ represents the resistance of the fourth resistor wiring 110D, R5′ represents the resistance of the fifth resistor wiring 110E, and R6′ represents the resistance of the sixth resistor wiring 110F.

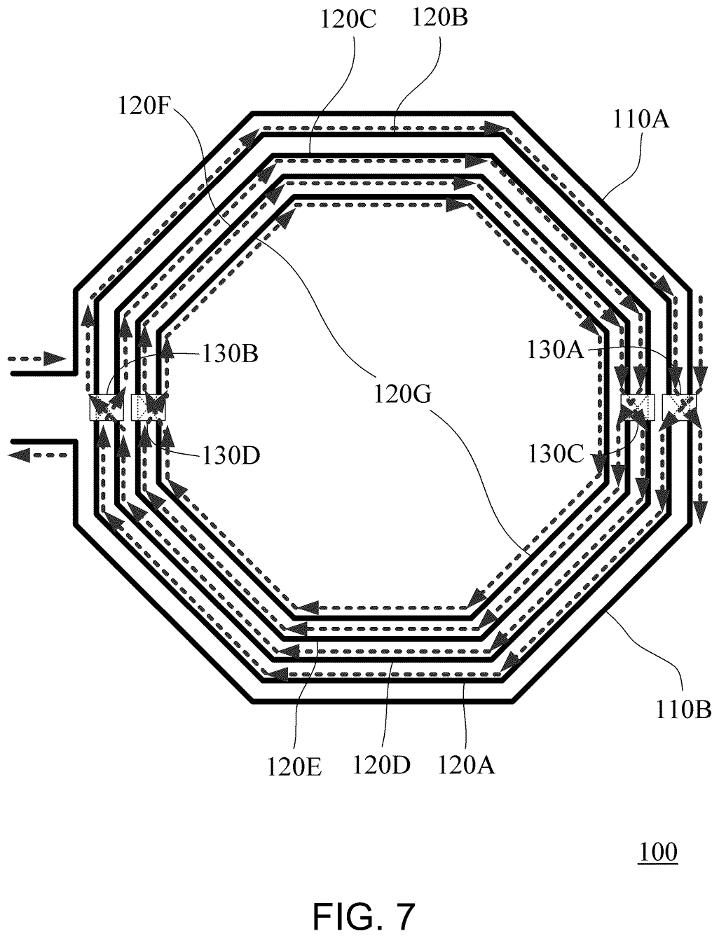

FIG. 7 schematically illustrate a top view of the variable resistor 100 operated in an operation mode in accordance with the fifth embodiment of the disclosure.

Referring to FIG. 2A through FIG. 2D as well as FIG. 7, the second switch 134A of the first node or switch circuit 130A, the third switch 136A of the first node or switch circuit 130A, the second switch 134B of the second node or switch circuit 130B, the third switch 136B of the second node or switch circuit 130B, the second switch 134C of the third node or switch circuit 130C, the third switch 136C of the third node or switch circuit 130C, the second switch 134D of the fourth node or switch circuit 130D, and the third switch 136D of the fourth node or switch circuit 130D are turned-on or enabled, and the rest of the switches (i.e., the first switch 132A of the first node or switch circuit 130A, the first switch 132B of the second node or switch circuit 130B, the first switch 132C of the third node or switch circuit 130C and the first switch 132D of the fourth node or switch circuit 130D) are turned-off or disabled. Under such operation mode, the first resistor wiring 110A, the first spare resistor wiring 120A, the third spare resistor wiring 120C, the fifth spare resistor wiring 120E, the seventh spare resistor wiring 120G, the sixth spare resistor wiring 120F, the fourth spare resistor wiring 120D, the second spare resistor wiring 120B and the second resistor wiring 110B are electrically connected in series by the second switch 134A of the first node or switch circuit 130A, the third switch 136A of the first node or switch circuit 130A, the second switch 134B of the second node or switch circuit 130B, the third switch 136B of the second node or switch circuit 130B, the second switch 134C of the third node or switch circuit 130C, the third switch 136C of the third node or switch circuit 130C, the second switch 134D of the fourth node or switch circuit 130D, and the third switch 136D of the fourth node or switch circuit 130D.

Under such operation mode, when a current is applied from the current input end of the first resistor wiring 110A, flows through the first resistor wiring 110A, the first spare resistor wiring 120A, the third spare resistor wiring 120C, the fifth spare resistor wiring 120E, the seventh spare resistor wiring 120G, the sixth spare resistor wiring 120F, the fourth spare resistor wiring 120D, the second spare resistor wiring 120B and the second resistor wiring 110B of the variable resistor 100, and outputs from the current input end of the second resistor wiring 110B, the variable resistor 100 provides a resistance about (R1+R1′+R3′+R5′+R7′+R6′+R4′+R2′+R2) Ohm, where R1 represents the resistance of the first resistor wiring 110A, R1′ represents the resistance of the first spare resistor wiring 120A, R2 represents the resistance of the second resistor wiring 110B, R2′ represents the resistance of the second spare resistor wiring 120B, R3′ represents the resistance of the third resistor wiring 110C, R4′ represents the resistance of the fourth resistor wiring 110D, R5′ represents the resistance of the fifth resistor wiring 110E, R6′ represents the resistance of the sixth resistor wiring 110F, and R7′ represents the resistance of the seventh resistor wiring 110G.

FIG. 8A schematically illustrates a perspective view of a metal-oxide-semiconductor field effect transistor (MOSFET) fabricated by Front-End-of Line (FEOL) processes. FIG. 8B schematically illustrates a perspective view of a thin film transistor (TFT) fabricated by Back-End-of Line (BEOL) processes.

As illustrated in FIG. 8A, the fabrication of the variable resistor 100 is integrated in the fabrication of a semiconductor die or a semiconductor wafer 200 including a semiconductor substrate 210 and an interconnect structure 220 formed on the semiconductor substrate 210. For example, the first resistor wiring 110A, the second resistor wiring 110B, the first spare resistor wiring 120A, the second spare resistor wiring 120B, the third spare resistor wiring 120C, the fourth spare resistor wiring 120D, the fifth spare resistor wiring 120E, the sixth spare resistor wiring 120F and the seventh spare resistor wiring 120G (shown in FIG. 1) are formed in the interconnect structure 220 of the semiconductor die or the semiconductor wafer 200. Furthermore, the switches (i.e., the first switches 132A, 132B, 132C, 132D, the second switch 134A, 134B, 134C, 134D, and the third switches 136A, 136B, 136C, 136D) of the first node or switch circuit 130A, the second node or switch circuit 130B, the third node or switch circuit 130C and the fourth node or switch circuit 130D are formed in the semiconductor substrate 210 of the semiconductor die or the semiconductor wafer 200. In other words, the resistor wirings of the variable resistor 100 are formed within the interconnect structure 220 through Back-End-of Line (BEOL) processes of the semiconductor die or the semiconductor wafer 200, and the switch circuits of the variable resistor 100 are formed within the semiconductor substrate 210 through Front-End-of Line (FEL) processes of the semiconductor die or the semiconductor wafer 200.

As illustrated in FIG. 8B, the fabrication of the variable resistor 100 is integrated in the fabrication of a semiconductor die or a semiconductor wafer 200 including a semiconductor substrate 210 and an interconnect structure 220 formed on the semiconductor substrate 210. For example, the first resistor wiring 110A, the second resistor wiring 110B, the first spare resistor wiring 120A, the second spare resistor wiring 120B, the third spare resistor wiring 120C, the fourth spare resistor wiring 120D, the fifth spare resistor wiring 120E, the sixth spare resistor wiring 120F and the seventh spare resistor wiring 120G (shown in FIG. 1) are formed in the interconnect structure 220 of the semiconductor die or the semiconductor wafer 200. Furthermore, the switches (i.e., the first switches 132A, 132B, 132C, 132D, the second switch 134A, 134B, 134C, 134D, and the third switches 136A, 136B, 136C, 136D) of the first node or switch circuit 130A, the second node or switch circuit 130B, the third node or switch circuit 130C and the fourth node or switch circuit 130D are formed in the interconnect structure 220 of the semiconductor die or the semiconductor wafer 200. In other words, the variable resistor 100 are formed within the interconnect structure 220 through Back-End-of Line (BEOL) processes of the semiconductor die or the semiconductor wafer 200.

The resistance of the above-mentioned variable resistor 100 (shown in FIGS. 3-7) can be electronically modulated through switching nodes. Different operation modes can be determined by the switching nodes (i.e., the nodes 130A, 130B, 130C, 130D) such that the variable resistor 100 may provide various resistance values. Accordingly, design flexibility of the variable resistor 100 may be significantly enhanced.

In accordance with some embodiments of the present disclosure, a resistor including a first resistor wiring, a second resistor wiring, a first spare resistor wiring, a first node, a second spare resistor wiring and a second node is provided. The first resistor wiring is electrically connected to the second resistor wiring through a first switch of the first node, and the first resistor wiring is electrically connected to the first spare resistor wiring through a second switch of the first node. The first spare resistor wiring is electrically connected to the second spare resistor wiring through the second node, and the second spare resistor wiring is electrically connected to the second resistor wiring through a third switch of the first node. In some embodiments, the resistor further includes a third spare resistor wiring, a fourth spare resistor wiring and a third node, wherein the first spare resistor wiring is electrically connected to the second spare resistor wiring through a first switch of the second node, and the first spare resistor wiring is electrically connected to the third spare resistor wiring through a second switch of the second node, and wherein the third spare resistor wiring is electrically connected to the fourth spare resistor wiring through the third node, and the fourth spare resistor wiring is electrically connected to the second spare resistor through a third switch of the second node. In some embodiments, the first spare resistor wiring is between the second resistor wiring and the fourth spare resistor wiring, and the second spare resistor wiring is between the first resistor wiring and the third spare resistor wiring. In some embodiments, the resistor further includes a fifth spare resistor wiring, a sixth spare resistor wiring and a fourth node, wherein the third spare resistor wiring is electrically connected to the fourth spare resistor wiring through a first switch of the third node, and the third spare resistor wiring is electrically connected to the fifth spare resistor wiring through a second switch of the third node, and wherein the fifth spare resistor wiring is electrically connected to the sixth spare resistor wiring through the fourth node, and the sixth spare resistor wiring is electrically connected to the fourth spare resistor through a third switch of the third node. In some embodiments, the third spare resistor wiring is between the second spare resistor wiring and the sixth spare resistor wiring, and the fourth spare resistor wiring is between the first spare resistor wiring and the fifth spare resistor wiring. In some embodiments, the resistor further includes a seventh spare resistor wiring, wherein a first end of the seventh spare resistor wiring is electrically connected to the fifth spare resistor wiring through a first switch of the fourth node, and a second end of the seventh spare resistor wiring is electrically connected to the fifth spare resistor wiring through a second switch of the fourth node. In some embodiments, the sixth spare resistor wiring is between the third spare resistor wiring and the seventh spare resistor wiring, and the fifth spare resistor wiring is between the fourth spare resistor wiring and the seventh spare resistor wiring. In some embodiments, the seventh spare resistor wiring comprises a ring-shaped resistor wiring. In some embodiments, the first resistor wiring, the second resistor wiring, the first spare resistor wiring, the second spare resistor wiring, the third spare resistor wiring, the fourth spare resistor wiring, the fifth spare resistor wiring and the sixth spare resistor wiring are distributed outside an area surrounded by the seventh spare resistor. In some embodiments, the first spare resistor wiring, the second spare resistor wiring, the third spare resistor wiring, the fourth spare resistor wiring, the fifth spare resistor wiring, the sixth spare resistor wiring and the seven spare resistor wiring are distributed in an area surrounded by the first resistor wiring and the second resistor wiring.

In accordance with some embodiments of the present disclosure, a resistor including a first resistor wiring, a second resistor wiring, a first spare resistor wiring, a second spare resistor wiring, a first switch circuit and a second switch circuit is provided. The first resistor wiring and the second resistor wiring are distributed along a first ring-shaped layout path. The first spare resistor wiring and the second spare resistor wiring are distributed along a second ring-shaped layout path. The first resistor wiring is electrically connected to the second resistor wiring through a first transistor of the first switch circuit, and the first resistor wiring is electrically connected to the first spare resistor wiring through a second transistor of the first switch circuit. The first spare resistor wiring is electrically connected to the second spare resistor wiring through the second switch circuit, and the second spare resistor wiring is electrically connected to the second resistor wiring through a third transistor of the first switch circuit. In some embodiments, the resistor further includes a third spare resistor wiring, a fourth spare resistor wiring a third switch circuit, wherein the first spare resistor wiring is electrically connected to the second spare resistor wiring through a first transistor of the second switch circuit, and the first spare resistor wiring is electrically connected to the third spare resistor wiring through a second transistor of the second switch circuit, and wherein the third spare resistor wiring is electrically connected to the fourth spare resistor wiring through the third switch circuit, and the fourth spare resistor wiring is electrically connected to the second spare resistor through a third transistor of the second switch circuit. In some embodiments, the third spare resistor wiring and the fourth spare resistor wiring are distributed along a third ring-shaped layout path. In some embodiments, the resistor further includes a fifth spare resistor wiring, a sixth spare resistor wiring and a fourth switch circuit, wherein the third spare resistor wiring is electrically connected to the fourth spare resistor wiring through a first transistor of the third switch circuit, and the third spare resistor wiring is electrically connected to the fifth spare resistor wiring through a second transistor of the third switch circuit, and wherein the fifth spare resistor wiring is electrically connected to the sixth spare resistor wiring through the fourth switch circuit, and the sixth spare resistor wiring is electrically connected to the fourth spare resistor through a third transistor of the third switch circuit. In some embodiments, the fifth spare resistor wiring and the sixth spare resistor wiring are distributed along a fourth ring-shaped layout path. In some embodiments, the resistor further includes a seventh spare resistor wiring, wherein a first end of the seventh spare resistor wiring is electrically connected to the fifth spare resistor wiring through a first transistor of the fourth switch circuit, and a second end of the seventh spare resistor wiring is electrically connected to the fifth spare resistor wiring through a second transistor of the fourth switch circuit. In some embodiments, the first transistor of the first switch circuit, the second transistor of the first switch circuit and the third transistor of the first switch circuit comprise metal-oxide-semiconductor field effect transistors. In some embodiments, the first transistor of the first switch circuit, the second transistor of the first switch circuit and the third transistor of the first switch circuit comprise thin film transistors.

In accordance with some embodiments of the present disclosure, a method including the following steps is provided. A first resistor wiring, a second resistor wiring and a spare resistor wiring are formed, wherein the first resistor wiring is electrically connected to a first end of the spare resistor wiring through a second transistor of the switch circuit, and a second end of the spare resistor wiring is electrically connected to the second resistor wiring through a third transistor of the switch circuit. A switch circuit is formed, wherein the first resistor wiring is electrically connected to the second resistor wiring through a first transistor of the switch circuit. In some embodiments, the first resistor wiring, the second resistor wiring and the spare resistor wiring are formed through back-end-of line processes, and wherein the first transistor, the second transistor and the third transistor comprise metal-oxide-semiconductor field effect transistors formed through front-end-of line processes and/or thin film transistors formed through back-end-of line processes.

In accordance with some embodiments of the present disclosure, a resistor including a first resistor wiring, a second resistor wiring, a switch circuit and a spare resistor wiring is provided. The first resistor wiring is electrically connected to the second resistor wiring through a first transistor of the switch circuit. The first resistor wiring is electrically connected to a first end of the spare resistor wiring through a second transistor of the switch circuit, and a second end of the spare resistor wiring is electrically connected to the second resistor wiring through a third transistor of the switch circuit. In some embodiments, the first transistor, the second transistor and the third transistor comprise metal-oxide-semiconductor field effect transistors and/or thin film transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first resistor wiring;
a second resistor wiring;
a first spare resistor wiring;
a first node, wherein the first resistor wiring is electrically connected to the second resistor wiring through a first switch of the first node, and the first resistor wiring is electrically connected to the first spare resistor wiring through a second switch of the first node;
a second spare resistor wiring; and
a second node, wherein the first spare resistor wiring is electrically connected to the second spare resistor wiring through the second node, and the second spare resistor wiring is electrically connected to the second resistor wiring through a third switch of the first node.

2. The semiconductor structure of claim 1 further comprising:
a third spare resistor wiring, wherein the first spare resistor wiring is electrically connected to the second spare resistor wiring through a first switch of the second node, and the first spare resistor wiring is electrically connected to the third spare resistor wiring through a second switch of the second node;
a fourth spare resistor wiring; and
a third node, wherein the third spare resistor wiring is electrically connected to the fourth spare resistor wiring through the third node, and the fourth spare resistor wiring is electrically connected to the second spare resistor through a third switch of the second node.

3. The semiconductor structure of claim 2, wherein the first spare resistor wiring is between the second resistor wiring and the fourth spare resistor wiring, and the second spare resistor wiring is between the first resistor wiring and the third spare resistor wiring.

4. The semiconductor structure of claim 2 further comprising:
a fifth spare resistor wiring, wherein the third spare resistor wiring is electrically connected to the fourth spare resistor wiring through a first switch of the third node, and the third spare resistor wiring is electrically connected to the fifth spare resistor wiring through a second switch of the third node;
a sixth spare resistor wiring; and
a fourth node, wherein the fifth spare resistor wiring is electrically connected to the sixth spare resistor wiring through the fourth node, and the sixth spare resistor wiring is electrically connected to the fourth spare resistor through a third switch of the third node.

5. The semiconductor structure of claim 4, wherein the third spare resistor wiring is between the second spare resistor wiring and the sixth spare resistor wiring, and the fourth spare resistor wiring is between the first spare resistor wiring and the fifth spare resistor wiring.

6. The semiconductor structure of claim 4 further comprising:
a seventh spare resistor wiring, wherein a first end of the seventh spare resistor wiring is electrically connected to the fifth spare resistor wiring through a first switch of the fourth node, and a second end of the seventh spare resistor wiring is electrically connected to the fifth spare resistor wiring through a second switch of the fourth node.

7. The semiconductor structure of claim 6, wherein the sixth spare resistor wiring is between the third spare resistor wiring and the seventh spare resistor wiring, and the fifth spare resistor wiring is between the fourth spare resistor wiring and the seventh spare resistor wiring.

8. The semiconductor structure of claim 6, wherein the seventh spare resistor wiring comprises a ring-shaped resistor wiring.

9. The semiconductor structure of claim 8, wherein the first resistor wiring, the second resistor wiring, the first spare resistor wiring, the second spare resistor wiring, the third spare resistor wiring, the fourth spare resistor wiring, the fifth spare resistor wiring and the sixth spare resistor wiring are distributed outside an area surrounded by the seventh spare resistor.

10. The semiconductor structure of claim 6, wherein the first spare resistor wiring, the second spare resistor wiring, the third spare resistor wiring, the fourth spare resistor wiring, the fifth spare resistor wiring, the sixth spare resistor wiring and the seven spare resistor wiring are distributed in an area surrounded by the first resistor wiring and the second resistor wiring.

11. A semiconductor structure, comprising:
a first resistor wiring;
a second resistor wiring, wherein the first resistor wiring and the second resistor wiring are distributed along a first ring-shaped layout path;
a first spare resistor wiring;
a second spare resistor wiring, wherein the first spare resistor wiring and the second spare resistor wiring are distributed along a second ring-shaped layout path;
a first switch circuit, wherein the first resistor wiring is electrically connected to the second resistor wiring through a first transistor of the first switch circuit, and the first resistor wiring is electrically connected to the first spare resistor wiring through a second transistor of the first switch circuit; and
a second switch circuit, wherein the first spare resistor wiring is electrically connected to the second spare resistor wiring through the second switch circuit, and the second spare resistor wiring is electrically connected to the second resistor wiring through a third transistor of the first switch circuit.

12. The semiconductor structure of claim 11 further comprising:
a third spare resistor wiring, wherein the first spare resistor wiring is electrically connected to the second spare resistor wiring through a first transistor of the second switch circuit, and the first spare resistor wiring is electrically connected to the third spare resistor wiring through a second transistor of the second switch circuit;
a fourth spare resistor wiring; and
a third switch circuit, wherein the third spare resistor wiring is electrically connected to the fourth spare resistor wiring through the third switch circuit, and the fourth spare resistor wiring is electrically connected to the second spare resistor through a third transistor of the second switch circuit.

13. The semiconductor structure of claim 12, wherein the third spare resistor wiring and the fourth spare resistor wiring are distributed along a third ring-shaped layout path.

14. The semiconductor structure of claim 12 further comprising:
a fifth spare resistor wiring, wherein the third spare resistor wiring is electrically connected to the fourth spare resistor wiring through a first transistor of the third switch circuit, and the third spare resistor wiring is electrically connected to the fifth spare resistor wiring through a second transistor of the third switch circuit;
a sixth spare resistor wiring; and
a fourth switch circuit, wherein the fifth spare resistor wiring is electrically connected to the sixth spare resistor wiring through the fourth switch circuit, and the sixth spare resistor wiring is electrically connected to the fourth spare resistor through a third transistor of the third switch circuit.

15. The semiconductor structure of claim 14, wherein the fifth spare resistor wiring and the sixth spare resistor wiring are distributed along a fourth ring-shaped layout path.

16. The semiconductor structure of claim 14 further comprising:
a seventh spare resistor wiring, wherein a first end of the seventh spare resistor wiring is electrically connected to the fifth spare resistor wiring through a first transistor of the fourth switch circuit, and a second end of the seventh spare resistor wiring is electrically connected to the fifth spare resistor wiring through a second transistor of the fourth switch circuit.

17. The semiconductor structure of claim 11, wherein the first transistor of the first switch circuit, the second transistor of the first switch circuit and the third transistor of the first switch circuit comprise metal-oxide-semiconductor field effect transistors.

18. The semiconductor structure of claim 11, wherein the first transistor of the first switch circuit, the second transistor of the first switch circuit and the third transistor of the first switch circuit comprise thin film transistors.

19. A method, comprising:
forming a first resistor wiring, a second resistor wiring and a spare resistor wiring, wherein the first resistor wiring is electrically connected to a first end of the spare resistor wiring through a second transistor of the switch circuit, and a second end of the spare resistor wiring is electrically connected to the second resistor wiring through a third transistor of the switch circuit; and
forming a switch circuit, wherein the first resistor wiring is electrically connected to the second resistor wiring through a first transistor of the switch circuit.

20. The method of claim 19, wherein the first resistor wiring, the second resistor wiring and the spare resistor wiring are formed through back-end-of line processes, and wherein the first transistor, the second transistor and the third transistor comprise metal-oxide-semiconductor field effect transistors formed through front-end-of line processes and/or thin film transistors formed through back-end-of line processes.
